(19) United States
(12) Patent Application Publication
(10) Pub. No.: US 2008/0001262 A1
(43) Pub. Date: Jan. 3, 2008

(54) Silicon level solution for mitigation of substrate noise

(76) Inventor: Telesphor Kamgaing, Chandler, AZ (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/479,583

(22) Filed: Jun. 29, 2006

(51) Int. Cl. H01L 23/552

(52) U.S. Cl. 257/659; 257/660; 257/E21.54

(57) ABSTRACT

The techniques described herein reduce the substrate noise current that exists when digital and analog components reside on the same microelectronic die. Single or multiple rows of isolation vias form isolation barriers between the individual circuit blocks. The isolation vias may be hollow or (lined or filled) with a conductive or non-conductive material.

### TECHNICAL FIELD

Embodiments of the invention relate to mixed-signal integrated circuits. More particularly, embodiments of the invention relate to a silicon level solution that may reduce substrate-induced digital noise that can occur when digital and non-digital circuit blocks reside on the same microelectronic die.

### BACKGROUND

In general, there have been two solutions for creating wireless radio systems where digital circuitry and analog RF components reside in the same package. The first solution is to create one microelectronic die for the digital circuitry and another for the analog RF components and then connect them within a single package. The negative aspect of this solution is the high costs associated with singulation and multiple assemblies. The second solution is to have both components created in a single microelectronic die. One negative aspect of this solution concerns the interference one component can impose on the other. Embodiments of this invention address this negative aspect of the second solution.

FIG. 1 is a conceptual illustration of substrate noise current 110. When both digital 100 and analog 105 circuitries reside on the same microelectronic die, components can interfere with one another. For example, if several CMOS transistors switch at the same time, substrate noise current 110 is injected into the silicon substrate 120. While some current flows to the back metallization 130, the remaining current may change the overall potential of the substrate at different locations, which in turn may lead to the malfunctioning of sensitive RF/analog circuits. Other key concerns are digital-to-digital noise interference (e.g. noise generating by a digital circuit such a baseband/MAC or a processor can generate jitters in the clock signal.)

FIG. 2 is a cross section of an existing solution for a single die mixed-signal device. Presently the problems created by substrate noise current are solved either at the package level through the aforementioned process of combining separate microelectronic dice, or at the chip level through the use of deep wells 220 (either n-type or p-type). These wells 220 are regions around circuitry doped inversely (n or p) to create an inherent pn junction that acts as a diode and prevents signal transmission from, in this example, digital circuitry 200 to the analog circuitry 210 when the well 220 is properly reversed-biased. This chip level solution requires constant biasing of the well junction 220 in order to achieve reverse biasing. This chip level solution also requires both power to be supplied to the well 220 to activate it and volume within the substrate 230 to accommodate the well 220. Furthermore, at very high frequencies the parasitic capacitance of the junction may continue to provide a conductive path to the substrate noise current independent of the reverse bias voltage.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a cross section of one embodiment of a single chip wireless radio system illustrating substrate noise current.

FIG. 2 is a cross section of a well junction.

FIG. 3 is a cross-section illustration of one embodiment of a microelectronic die with a photoresist mask.

FIG. 4 is a cross-section illustration of one embodiment of a microelectronic die with hollow isolation vias.

FIG. 5 is a cross-section illustration of one embodiment of a microelectronic die with metal-filled isolation vias.

FIG. 6 is a cross-section illustration of one embodiment of a microelectronic die with metal-lined isolation vias.

FIG. 7 illustrates the operation of one embodiment of a microelectronic die from a side-view perspective.

FIG. 8 is a top view (with silicon backend not shown) of one embodiment of a microelectronic die containing a plurality of isolation vias with a staggered row depth of two.

FIG. 9 is a cross section illustration of one embodiment of a microelectronic die containing isolation vias.

FIG. 10 is a cross section illustration of one embodiment of a microelectronic die containing hollow isolation vias with backend interconnectivity attached.

FIG. 11 is a block diagram of one embodiment of a system with isolation vias between circuit blocks.

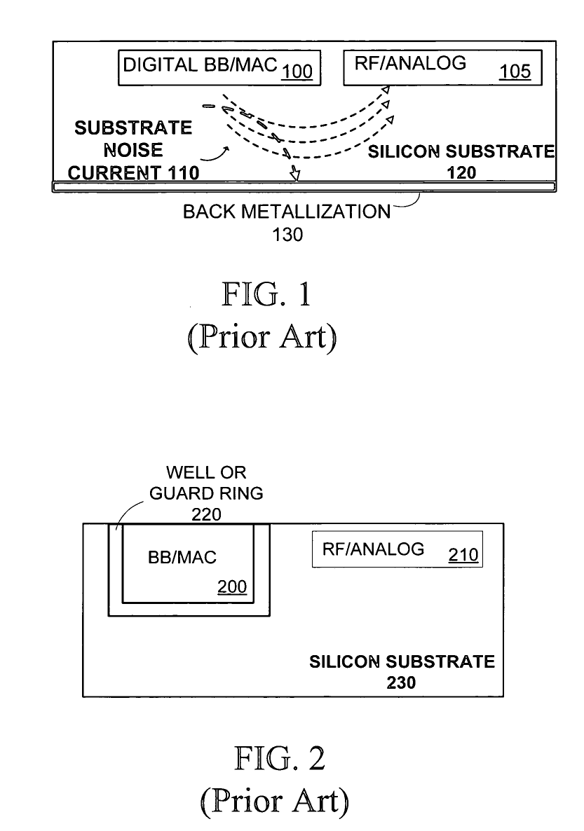

### DETAILED DESCRIPTION

In the following description, numerous specific details are set forth. However, embodiments of the invention may be practiced without these specific details. In other instances well-known circuits, structures and techniques have not been shown in detail in order not to obscure the understanding of this description.

The techniques described herein may reduce the substrate noise current that exists when digital and analog components reside on the same microelectronic die. Single or multiple rows of isolation vias may form current barriers between the individual circuit blocks (e.g., between switching CMOS circuitry and analog RF circuitry). The isolation vias may be hollow, lined or filled with a conductive or non-conductive material. Substrate current is redirected more efficiently when the isolation vias are lined or filled with a conductive metal; however, this process incurs the expense of more production steps. In the description that follows, isolation vias are generally depicted as cylindrical, however, the isolation vias may be any shape (e.g., square, elliptical) or size.

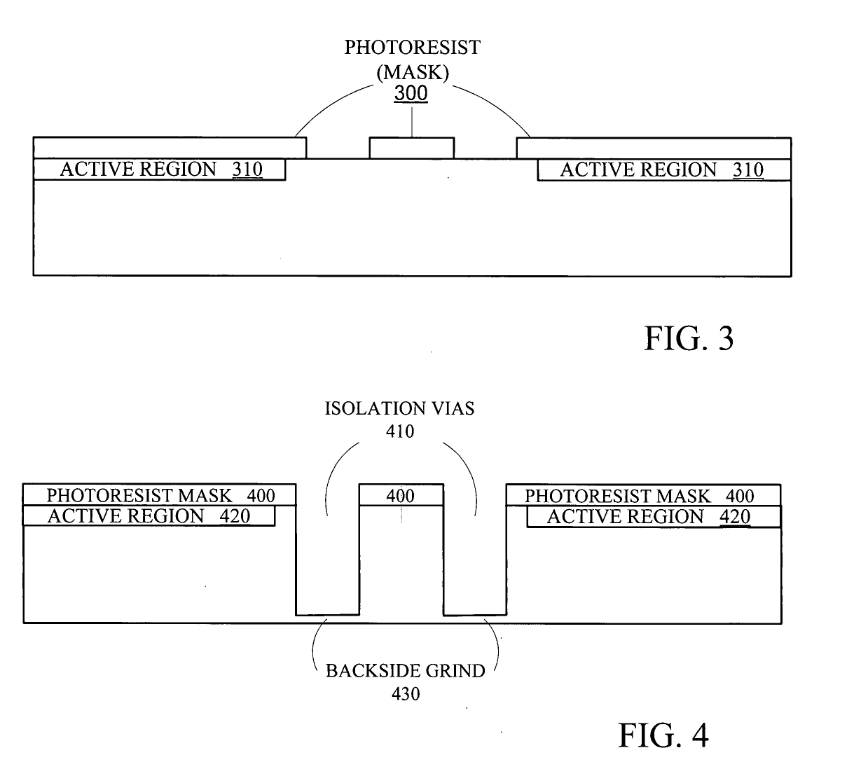

FIG. 3 is a cross-section illustration of one embodiment of a microelectronic die with a photoresist mask 300 configured for the creation of isolation vias between active regions 310. FIG. 3 illustrates the process for creation of the isolation vias after the active regions 310 of the microelectronic die are manufactured using any process known in the art and may include either digital or analog circuitry. The microelectronic die may be coated with a photoresist mask 300, forming a pattern layer wherein openings form isolation vias and active regions are covered. Any technique known in the art to deposit (or otherwise apply) the photoresist 300 may be utilized. Also, any technique known in the art to expose the via regions may be utilized.

FIG. 4 is a cross-section illustration of one embodiment of a microelectronic die with hollow isolation vias 410 etched partially through the silicon. Isolation vias may be created by areas of the microelectronic die exposed from the photoresist mask 400 through the use of, for example, “wet etching” or “dry etching.” Isolation vias 410 between the active regions 420 may be formed once the etching is complete. The microelectronic die may be etched completely through the silicon, or partially through, where the remaining portions of the die 430 may be reduced via backside surface grinding.

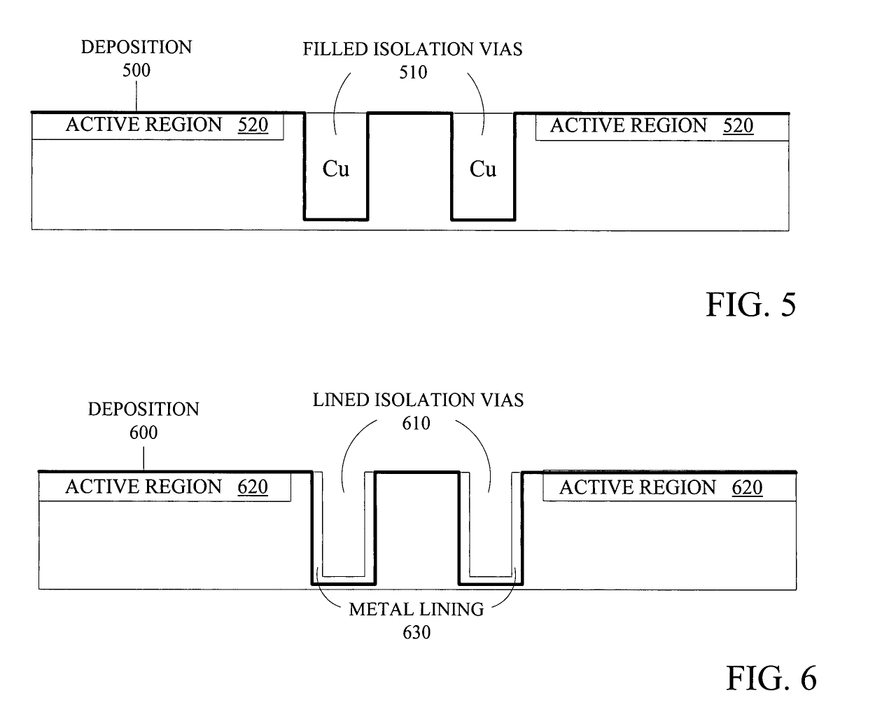

FIG. 5 is a cross-section illustration of one embodiment of a microelectronic die with metal-filled isolation vias 510. The example in FIG. 5 illustrates the method of subjecting the microelectronic die to a deposition process 500, which may be any process that grows, coats, or otherwise transfers a material onto the microelectronic die. Any deposition process known in the art may be used. After the deposition process the isolation vias 510 between the active regions 520 may be filled with conductive metal (e.g. copper, aluminum). Any technique known in the art suitable for metal deposition may be used.

FIG. 6 is a cross section of one of a microelectronic die with metal-lined isolation vias. The example in FIG. 6 illustrates the method of subjecting the microelectronic die to a deposition process 600, which may be any process that grows, coats, or otherwise transfers a material onto the microelectronic die. After the deposition process the isolation vias 610 between the active regions 620 may be electroplated with conductive metal (e.g. copper, aluminum) walls 630. Any technique known in the art for lining via walls and/or electroplating may be utilized.

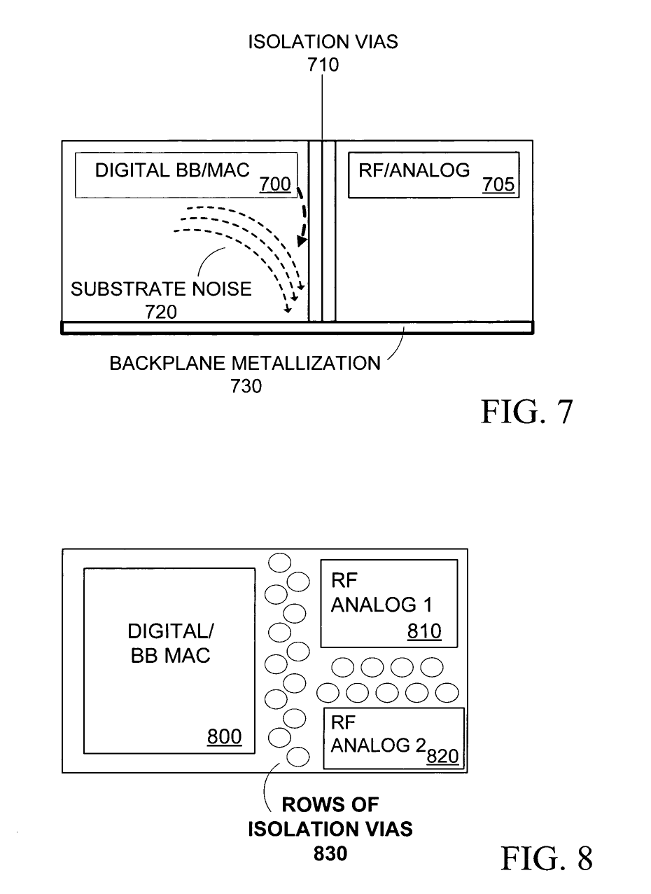

FIG. 7 illustrates the operation of one embodiment of a microelectronic die having isolation vias from a side-view perspective. The isolation vias 710 are positioned between digital circuitry 700 and analog circuitry 705 and may be connected to backplane metallization 730, which is typically used as ground for the microelectronic die. Substrate noise 720 generated by the digital circuitry is redirected to the ground plane so as to not affect analog circuitry 705. In the absence of a backplane metallization 730 (i.e. thinned microelectronic die) isolation vias 710 may be tied together through a metal strip, which may be connected to ground.

In one embodiment, a single row of isolation vias will be sufficient to provide isolation. In another embodiment, staggered rows, at least two isolation vias deep, may create a barrier with no direct path for the current to flow between circuitries.

FIG. 8 is a top view (with silicon backend not shown) of one embodiment of a microelectronic die containing a plurality of isolation vias 830 with a staggered row depth of two. FIG. 8 illustrates how staggered rows 830 can prevent a direct current path between circuitries 800, 810 and 820. In the example of FIG. 8, each circuit block (e.g., 800, 810, 820) facing another circuit block may have isolation vias between the circuit blocks.

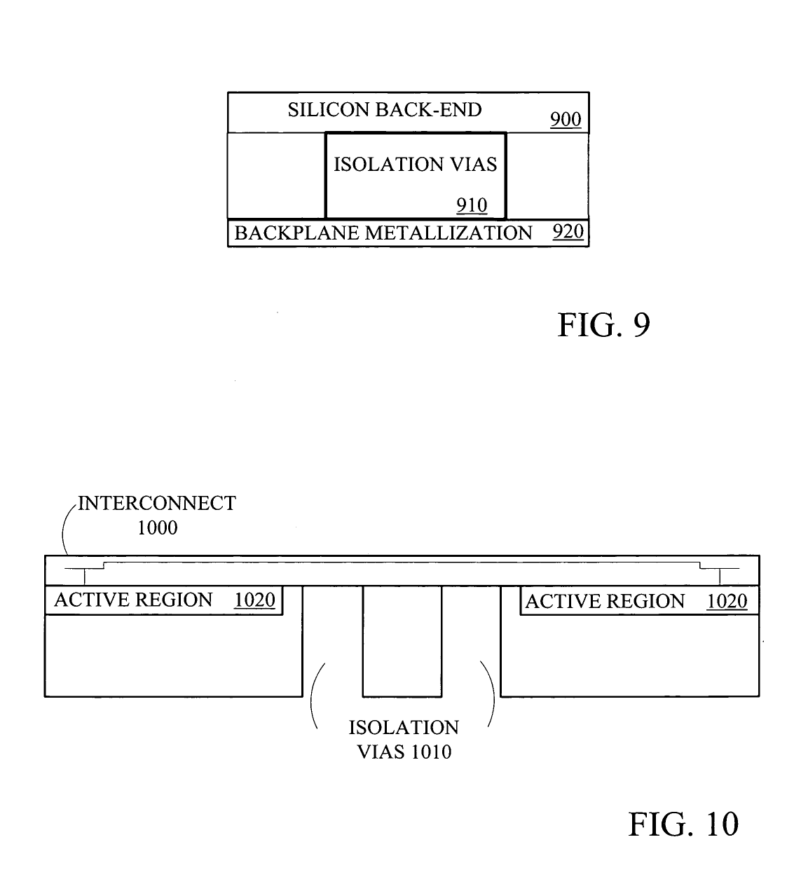

The height of the isolation vias may be through the silicon only so as to not affect the back-end where chip interconnectivity exists. This particular embodiment will not affect connectivity between the digital and analog circuitry. FIG. 9 is an illustration of one embodiment of a microelectronic die containing isolation vias 910 that are created through the silicon only, between the silicon back-end 900 and the backplane metallization 920.

FIG. 10 is a cross section of one embodiment of a microelectronic die containing hollow isolation vias 1010 with backend interconnectivity 1000 layers. The example in FIG. 10 illustrates how the connectivity 1000 to the active regions 1020 may be isolated and unaffected by the presence of isolation vias 1010.

If isolation vias are placed periodically, then they may create an electromagnetic band-gap structure. This structure may provide an additional electromagnetic band at high frequencies. This band-gap structure may be suitable for high frequency applications (e.g. radar applications that operate at 77 GHz) for which the present state of the art is not suitable.

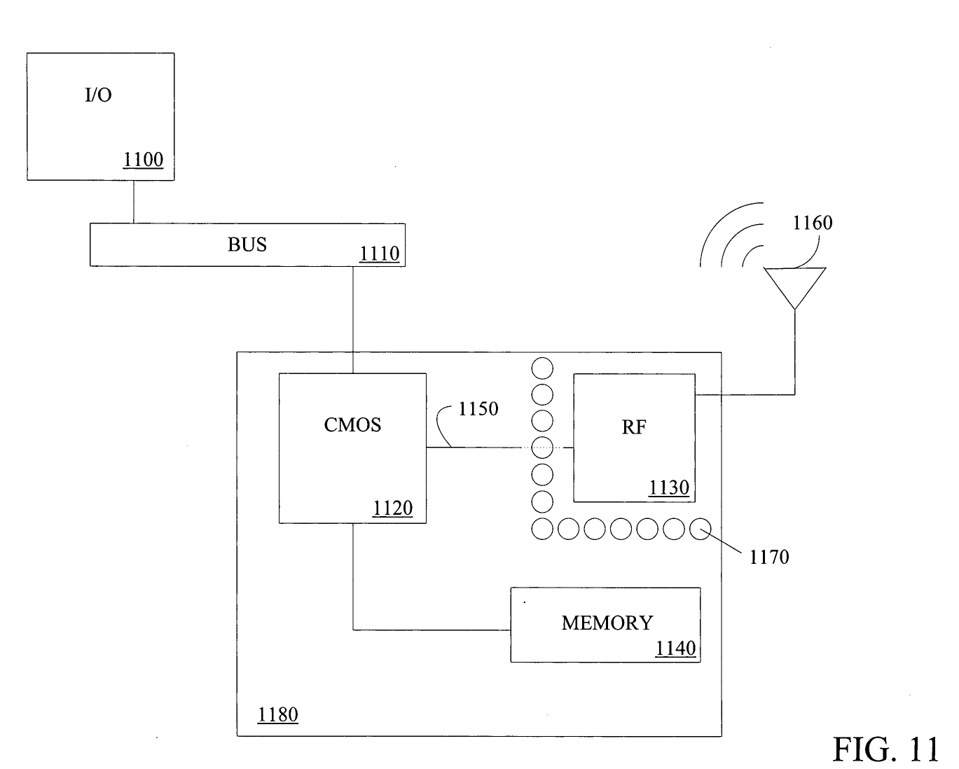

FIG. 11 is a block diagram of one embodiment of a system with isolation vias 1170 between circuit blocks 1120 and 1130. The example in FIG. 11 illustrates a system containing an I/O mechanism 1100, a bus 1110 and a microelectronic die 1180 connected to an antenna 1160. Antenna 1160 may be any type of antenna, for example, a substantially omnidirectional antenna, or antenna 1160 may represent an array of antennae. The RF component 1130 is isolated from CMOS circuitry 1120 and a memory component 1140 by a row of isolation vias 1170. The connectivity 1150 between the CMOS circuitry 1120 and the RF component 1130 runs on a plane that is separate from the isolation vias 1170.

Reference in the specification to “one embodiment” or “an embodiment” means that a particular feature, structure or characteristic described in connection with the embodiment is included in at least one embodiment of the invention. The appearances of the phrase “in one embodiment” in various places in the specification are not necessarily all referring to the same embodiment.

While the invention has been described in terms of several embodiments, those skilled in the art will recognize that the invention is not limited to the embodiments described, but can be practiced with modification and alteration within the spirit and scope of the appended claims. The description is thus to be regarded as illustrative instead of limiting.

We claim:

1. An apparatus comprising:
digital functional circuitry on a first portion of a microelectronic die; and
analog radio frequency (RF) circuitry on a second portion of the microelectronic die; and
a plurality of isolation vias disposed between the digital functional circuitry and the analog RF circuitry, wherein the plurality of isolation vias are isolated from the interconnectivity between the digital functional circuitry and the analog RF circuitry.

2. The apparatus of claim 1 wherein the digital functional circuitry comprises complementary metal oxide semiconductor (CMOS) circuitry.

3. The apparatus of claim 1 wherein the digital functional circuitry comprises media access control (MAC) circuitry.

4. The apparatus of claim 1 wherein the analog RF circuitry comprises wireless local area network (WLAN) frequency circuitry.

5. The apparatus of claim 4 wherein the WLAN circuitry conforms to an IEEE 802.11 standard.

6. The apparatus of claim 1 wherein the analog RF circuitry comprises radar frequency circuitry.

7. The apparatus of claim 1 wherein the analog RF circuitry comprises Worldwide Interoperability for Microwave Access (WiMAX) frequency circuitry.

8. The apparatus of claim 7 wherein the WiMAX circuitry conforms to an IEEE 802.16 standard.

9. The apparatus of claim 1 wherein the plurality of isolation vias are filled with metal.

10. The apparatus of claim 1 wherein the plurality of isolation vias are lined with metal.

11. The apparatus of claim 1 wherein the plurality of isolation vias comprise two rows of isolation vias where the first row is physically offset with respect to the second row.

12. The apparatus of claim 11 wherein a distance between isolation vias of the first row is approximately equal to a width of isolation vias of the second row.

13. The apparatus of claim 1 wherein the plurality of isolation vias are placed periodically to provide an electromagnetic band-gap structure, which provides current isolation up to 77 GHz.

14. A system comprising:
digital functional circuitry on a first portion of a microelectronic die; and
analog radio frequency (RF) circuitry on a second portion of the microelectronic die;
a plurality of isolation vias disposed between the digital functional circuitry and the analog RF circuitry on the microelectronic die, wherein the plurality of isolation vias are isolated from the interconnectivity between the digital functional circuitry and the analog RF circuitry; and
a substantially omnidirectional antenna coupled with the analog RF circuitry.

15. The system of claim 14 wherein the digital functional circuitry comprises complementary metal oxide semiconductor (CMOS) circuitry.

16. The system of claim 14 wherein the analog RF circuitry comprises radar frequency circuitry.

17. The system of claim 14 wherein the analog RF circuitry transmits data according to an IEEE 802 standard.

18. The system of claim 14 wherein the plurality of isolation vias are filled with metal.

19. The system of claim 14 wherein the plurality of isolation vias are lined with metal.

20. The system of claim 14 wherein the plurality of isolation vias comprise two rows of isolation vias where the first row is physically offset with respect to the second row.

21. The system of claim 20 wherein a distance between isolation vias of the first row is approximately equal to a width of isolation vias of the second row.

22. The apparatus of claim 14 wherein the plurality of isolation vias are placed periodically to provide an electromagnetic band-gap structure, which provides current isolation up to 77 GHz.

23. A method comprising:
forming active regions on a microelectronic die wherein at least one region is configured for digital circuitry and at least one region is configured for analog radio frequency (RF) circuitry;
forming a plurality of isolation vias between digital functional circuitry and analog RF circuitry, wherein the plurality of isolation vias are isolated from the interconnectivity between the digital functional circuitry and the analog RF circuitry.

24. The method of claim 23 wherein the digital functional circuitry comprises complementary metal oxide semiconductor (CMOS) circuitry.

25. The method of claim 23 wherein the analog RF circuitry comprises wireless local area network (WLAN) frequency circuitry.

26. The method of claim 23 wherein the analog RF circuitry comprises radar frequency circuitry.

27. The method of claim 23 wherein the analog RF circuitry comprises Worldwide Interoperability for Microwave Access (WiMAX) frequency circuitry.

28. The method of claim 23 wherein the plurality of isolation vias are filled with metal.

29. The method of claim 23 wherein the plurality of isolation vias are lined with metal.
